(19) United States
(12) Patent Application Publication
(10) Pub. No.: US 2008/0157268 A1
(43) Pub. Date: Jul. 3, 2008

(54) Fuse Element Using Low-K Dielectric

(76) Inventors: Deok-kee Kim, Bedford Hills, NY (US); Anil K. Chinthakindi, Haymarket, VA (US); Kelly Malone, Poughkeepsie, NY (US); Son Van Nguyen, Yorktown Heights, NY (US); Byeongju Park, Plainview, NY (US)

Correspondence Address: FREDERICK W. GIBB, III;Gibb & Rahman, LLC, 2568-A RIVA ROAD, SUITE 304, ANNAPOLIS, MD, 21401, US

(21) Appl. No.: 11/618,749

(22) Filed: Dec. 30, 2006

(51) Int. Cl. H01L 23/525

(52) U.S. Cl. 257/529; 257/E23.149

(57) ABSTRACT

A programmable structure such as a write once read many (WORM) or one time programmable read only memories (OTPROM) is disclosed herein. The structure includes a first conductor (such as copper) positioned within a substrate and a metal cap on the first conductor. A low-k dielectric is on the substrate and the metal cap. A tantalum nitride resistor is on the dielectric, and the resistor is positioned above the metal cap such that a programmable region of the dielectric is positioned between the resistor and the metal cap. The first conductor (including the metal cap), the programmable region of the dielectric, and the resistor form a metal-insulator-metal capacitor. Further, the programmable region of the dielectric is adapted to be permanently changed from heat produced by the resistor when a voltage difference is applied to the first and second ends of the resistor, respectively, through the first and second contacts. Thus, the capacitor comprises a first capacitance before the programmable region is permanently changed by the heat from the resistor and comprises a second capacitance after the programmable region is permanently changed by the heat from the resistor.

### BACKGROUND

1. Field of the Invention

The embodiments of the invention generally relate to programmable structures used in write once read many (WORM) or one time programmable read only memories (OTPROM) and, more particularly, to an improved structure and method that changes, and detects the change in capacitance of a capacitor within such memories.

2. Description of the Related Art

Fuse devices are used in numerous applications including redundancy implementation in memory arrays, field programmable arrays, voltage trimming resistors/capacitors, RF circuit tuning, electronic chip id, usage tracking/diagnostic data logs, to remotely disable a device/car that is reported stolen, random access memories (ROM), etc.

Fuse devices are realized using many different technologies and materials. As in U.S. patent Publication 2003/0123207 and U.S. Pat. No. 6,703,680 (incorporated herein by reference), electromigration or agglomeration of silicide can be used for fuse application, which is the electrically programmable fuse (eFUSE) that is commonly used today. Flash technology (U.S. patent Publication 2003/0145154 (incorporated herein by reference)) which traps charges inside the floating gate can be used as a fuse device. Or as in U.S. patent Publication 2006/0024429 (incorporated herein by reference), phase change materials such as GST (Ge₂Sb₂Te₅) or GeSbSi can be used in fuse devices as well as in non-volatile memories. Anti-fuse devices using gate oxide breakdown in a typical gate structure are used as well. In U.S. patent Publication 2006/0097325 (incorporated herein by reference), CA tungsten plug-silicon dioxide-copper metal structure is used for antifuse applications.

In the case of flash memories and memories using phase change materials, new materials and/or processing steps compared to the standard complementary metal oxide semiconductor (CMOS) processing are required. In the case of electromigration fuses, typically a high programming voltage is required to electromigrate the silicide. When the standard gate structure or material is changed, it may require additional processing steps to form the silicided polysilicon structure. Further, in the case of antifuse devices using gate oxide breakdown in a typical gate structure, high voltage is typically required.

### SUMMARY

A programmable structure such as a write once read many (WORM) or one time programmable read only memories (OTPROM) is disclosed herein. The structure includes a first conductor (such as copper) positioned within a substrate and a metal cap on the first conductor. A low-k dielectric is on the substrate and the metal cap. A tantalum nitride resistor is on the dielectric, and the resistor is positioned above the metal cap such that a programmable region of the dielectric is positioned between the resistor and the metal cap. Additional conductors identified as the first and second contacts are connected to first and second ends of the resistor. The first contact and the second contact are above and outside opposite sides of the metal cap and first conductor.

One feature herein is that the first conductor (including the metal cap), the programmable region of the dielectric, and the resistor form a metal-insulator-metal capacitor. Further, the programmable region of the dielectric is adapted to be permanently changed from heat produced by the resistor when a voltage difference is applied to the first and second ends of the resistor, respectively, through the first and second contacts. Thus, the capacitor comprises a first capacitance before the programmable region is permanently changed by the heat from the resistor and comprises a second capacitance after the programmable region is permanently changed by the heat from the resistor.

These and other aspects of the embodiments of the invention will be better appreciated and understood when considered in conjunction with the following description and the accompanying drawings. It should be understood, however, that the following descriptions, while indicating preferred embodiments of the invention and numerous specific details thereof, are given by way of illustration and not of limitation. Many changes and modifications may be made within the scope of the embodiments of the invention without departing from the spirit thereof, and the embodiments of the invention include all such modifications.

### BRIEF DESCRIPTION OF THE DRAWINGS

The embodiments of the invention will be better understood from the following detailed description with reference to the drawings, in which:

FIG. 1 comprises a schematic cross-sectional diagram of a programmable device according to embodiments herein; and

FIG. 2 comprises a schematic top-view diagram of a programmable device according to embodiments herein.

### DETAILED DESCRIPTION OF PREFERRED EMBODIMENTS

The embodiments of the invention and the various features and advantageous details thereof are explained more fully with reference to the non-limiting embodiments that are illustrated in the accompanying drawings and detailed in the following description. It should be noted that the features illustrated in the drawings are not necessarily drawn to scale. Descriptions of well-known components and processing techniques are omitted so as to not unnecessarily obscure the embodiments of the invention. The examples used herein are intended merely to facilitate an understanding of ways in which the embodiments of the invention may be practiced and to further enable those of skill in the art to practice the embodiments of the invention. Accordingly, the examples should not be construed as limiting the scope of the embodiments of the invention.

The embodiments herein present a copper-low k dielectric-TaN resistor fuse. This structure is made using conventional BEOL process and, therefore, does not require new or different equipment or materials. The first electrode can be the conventional M1 copper metal. The conventional low K dielectric used in the conventional back end of line processing (BEOL) for CMOS devices can be used as the dielectric of the inventive capacitor. A conventional TaN resistor is usually formed in BEOL for resistor applications and is used in the inventive structure as the resistor. Thus, while the inventive structure and its use are new, the materials and the processing steps are compatible with conventional systems.

With the present invention, the material property of the WORM element is changed using a heating element. By heating the dielectric (such as SiCOH) above 500 C using the resistor, the dielectric constant of SiCOH can be changed (approximately twice). In addition to the dielectric constant increase, SiCOH shrinks as it is heated, which increases the capacitance of the SiCOH dielectric capacitor as well. The capacitance change due to both the increase in the dielectric constant of the SiCOH and the decrease in the thickness of the SiCOH before and after programming allows easy sensing. By optimizing the structure, the invention can be operated at low voltages, which reduces the chip area by reducing the area occupied by the programming transistors since smaller programming transistors can be used.

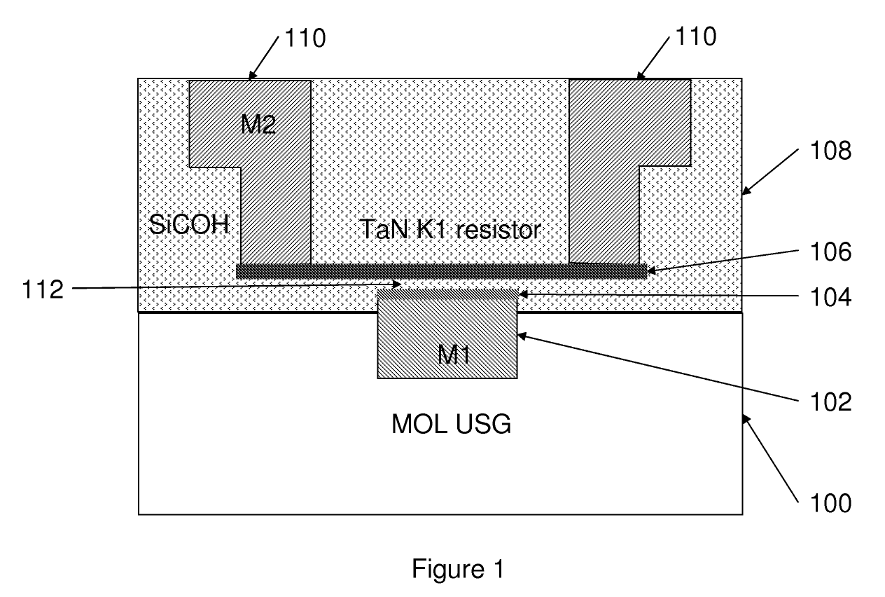

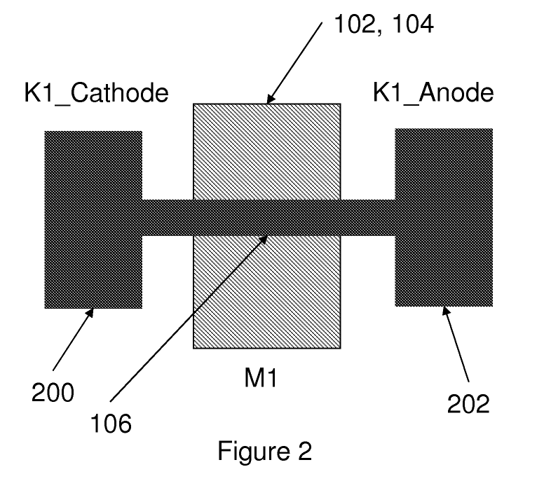

FIGS. 1 and 2 illustrate one embodiment of the invention. More specifically, FIG. 1 illustrates a portion of a programmable structure such as a write once read many (WORM) or one time programmable read only memories (OTPROM). The structure includes a copper conductor 102 positioned within a substrate 100 and a metal cap 104 on the first conductor 102. A low-k dielectric 108 is on the substrate 100, the copper conductor 102, and the metal cap 104. A tantalum nitride resistor 106 is positioned in the dielectric 108. The resistor 106 is positioned above the metal cap 104 such that a programmable region 112 of the dielectric 108 is positioned between the resistor 106 and the metal cap 104. Additional conductors 110 (identified as first and second contacts, for convenience) are connected to opposite (first and second) ends of the resistor 106. The first and second contacts 110 are above and outside the opposite sides of the metal cap 104.

One feature herein is that the first conductor 102 (including the metal cap 104) the programmable region 112 of the dielectric 108, and the resistor 106 form a metal-insulator-metal capacitor. Further, the programmable region 112 of the dielectric 108 is adapted to be permanently changed from heat produced by the resistor 106 when a voltage difference is applied to the first and second ends of the resistor 106, respectively, through the first and second contacts 110. More specifically, as shown in FIG. 2, when a voltage difference is applied between end 200 and the opposite end 202 of the resistor 106, the resistor generates heat. Thus, the capacitor comprises a first capacitance before the programmable region 112 is permanently changed by the heat from the resistor 106 and comprises a second capacitance after the programmable region 112 is permanently changed by the heat from the resistor 106.

Processing for the inventive structure is easily integrated into conventional CMOS processing. More specifically, the standard CMOS processing is performed up to the middle of the line processing, where the isolation structures and the transistors with sources/drains and gates are formed. After that, standard contact formation processing is performed. MOL dielectrics such as BPSG (borophosphosilicate glass) or USG (undoped silicate glass) are deposited and planarized using CMP (chemical mechanical polishing). And then, contact etching is done and W (tungsten) contacts are deposited and planarized. M1 metal lines are formed by the standard copper damascene process. M1 low K dielectrics are deposited and patterned for M1 copper lines. Copper is electroplated after barrier layers (TaN & Ta) and seed layers are sputter-deposited, after which the structure is planarized by CMP. With the invention, a metal cap such as CoWP (Cobalt, Tungsten, Phosphorus), CoWB (Cobalt, Tungsten, Boron), or Cu—Al alloys is deposited after the M1 copper metal is recessed. Subsequent planarization removes the metal cap layer from other areas. The M1 copper with the metal cap is used as the first electrode in the inventive structure. Then a thin layer of low K dielectric (e.g., 100 A of SiCOH) is deposited, and is used as the dielectric in the inventive fuse structure. Then a TaN K1 resistor of (e.g., 400 A, which can be used as the resistor as well as the second electrode in the inventive structure) is sputtered and patterned.

After this standard CMOS processing can be used to form contacts (V1) and the next level of metallization (M2 contacts). The low K dielectric (SiCOH) can be deposited and patterned for V1 and M2 formation. The barrier layers (TaN & Ta) and the copper seed layers are deposited, after which the copper is electroplated for V1 and M2 formation. The electroplated copper is planarized by CMP, which completes the V1& M2 formation. After that, standard CMOS BEOL processing is performed to complete the transistors/devices.

FIG. 2 shows how the inventive fuse device is programmed and sensed. In order to program, a voltage differential is applied between the K1 Cathode 200 and K1 Anode 202 to heat the resistor 106 and eventually heat the SiCOH 112 (which is between the M1 metal and K1 TaN resistor) above 500 C, which makes the dielectric constant and the thickness of the SiCOH change. It is well-known that the dielectric constant of SiCOH increases and the SiCOH shrinks when SiCOH is heated above 500 C. The change in the capacitance after programming is greater than two times the capacitance before programming.

In one example, a low K dielectric was used to measure the thickness change and the K value change after annealing experimentally. It densified after annealing and K value increased. However, the leakage was only slightly higher after annealing. Temperatures of 600 C were used to cause degradation of the SiCOH film. Outgasing of —CH3 material, drives out most Hydrogen and converts the film mostly to SiO₂ with some strong SiC phase film. The film is converted to SiO₂ and SiC phase, with little H left at 600 C. The K value of the low K dielectric with K value of 2.7 increased to 4.11 after annealing at 600 C in N₂ ambient.

Sensing can be done by measuring the capacitance between K1 Anode 202 and M1 level electrode 102. When the SiCOH dielectric is intact, the K value of the low K dielectric can be, for example, around 2.7. When it is programmed the K value of the low K dielectric can be made above 4. Sensing is done by measuring the change in the capacitance before and after programming.

The foregoing description of the specific embodiments will so fully reveal the general nature of the invention that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments of the invention have been described in terms of preferred embodiments, those skilled in the art will recognize that the embodiments of the invention can be practiced with modification within the spirit and scope of the appended claims.

What is claimed is:

1. A programmable structure comprising:
a substrate;
a first conductor positioned within said substrate;
a dielectric on said substrate;
a resistor positioned in said dielectric, wherein said resistor is positioned above said first conductor such that a programmable region of said dielectric is positioned between said resistor and said first conductor;
a first contact connected to a first end of said resistor; and
a second contact connected to a second end of said resistor,
wherein said first conductor, said programmable region of said dielectric, and said resistor form a capacitor, and
wherein said programmable region of said dielectric is adapted to be permanently changed from heat produced by said resistor when a voltage difference is applied to said first end of said resistor and said second end of said resistor, respectively, through said first contact and said second contact.

2. The structure according to claim 1, wherein said capacitor comprises a first capacitance before said programmable region is permanently changed by said heat and comprises a second capacitance after said programmable region is permanently changed by said heat.

3. The structure according to claim 1, wherein said dielectric comprises a low-k dielectric comprising SiCOH.

4. A programmable structure comprising:
a substrate;
a copper conductor positioned within said substrate;
a metal cap on said first conductor;
a dielectric on said substrate and said metal cap;
a tantalum nitride resistor positioned in said dielectric, wherein said resistor is positioned above said metal cap such that a programmable region of said dielectric is positioned between said resistor and said metal cap;
a first contact connected to a first end of said resistor; and
a second contact connected to a second end of said resistor,
wherein said first conductor, said metal cap, said programmable region of said dielectric and said resistor form a capacitor, and
wherein said programmable region of said dielectric is adapted to be permanently changed from heat produced by said resistor when a voltage difference is applied to said first end of said resistor and said second end of said resistor respectively through said first contact and said second contact.

5. The structure according to claim 4, wherein said capacitor comprises a first capacitance before said programmable region is permanently changed by said heat and comprises a second capacitance after said programmable region is permanently changed by said heat.

6. The structure according to claim 4, wherein said dielectric comprises a low-k dielectric comprising SiCOH.
